(19) United States
(12) Patent Application Publication
(10) Pub. No.: US 2026/0276685 A1
(43) Pub. Date: Sep. 17, 2026

(54) POWER CONSUMPTION CALCULATION DEVICE, METHOD, AND COMPUTER-READABLE MEDIUM

(71) Applicant: NEC Corporation, Tokyo (JP)

(72) Inventors: Jun TAKASAWA, Tokyo (JP); Kazuki OGATA, Tokyo (JP); Hideki KIKKAWA, Tokyo (JP); Yuji SATO, Tokyo (JP); Takashi TONEGAWA, Tokyo (JP)

(73) Assignee: NEC Corporation, Tokyo (JP)

(21) Appl. No.: 19/162,426

(22) PCT Filed: Mar. 20, 2023
(86) PCT No.: PCT/JP2023/010855

§ 371 Date: Sep. 5, 2025

(51) Int. Cl. G01R 22/06; G08G 1/01

(52) U.S. Cl. CPC G01R 22/061; G08G 1/0116

(57) ABSTRACT

An environmental factor acquisition unit acquires environmental factors in a place where a plurality of apparatuses are placed. Reference power consumption is set for each of the plurality of apparatuses. An individual power calculation unit estimates, for each of the plurality of apparatuses, individual power consumption of each of the plurality of apparatuses on the basis of the reference power consumption set for the apparatus and the acquired environmental factors.

### TECHNICAL FIELD

The present disclosure relates to a power consumption calculation device, a method, and a computer-readable medium.

### BACKGROUND ART

As a related art, PTL 1 discloses a cognitive power meter. The cognitive power meter described in PTL 1 has built-in intelligence, and divides one measured load signal into its components. The cognitive power meter uses model-based built-in intelligence to break down the power signal already measured at the input meter into its individual constituent loads and provide a usage summary to the consumer. The cognitive power meter decomposes the amount of power for each load such as an air conditioner, a dehumidifier, a general-purpose lighting, heating, a microwave oven, and a refrigerator. The functionality of the cognitive power meter described in PTL 1 is achieved in a residential power meter.

### Citation List

### Patent Literature

PTL 1: JP 2009-47694 A

### SUMMARY OF INVENTION

### Technical Problem

The cognitive power meter described in PTL 1 uses model-based built-in intelligence to divide one measured load signal into its components. However, the power consumption of individual components may vary depending on the environment of the place where each component is disposed. In PTL 1, since a change in environment is not considered, there is a possibility that one measured load signal cannot be accurately divided into its components in a case where an environmental factor changes.

In view of the above circumstances, an object of the present disclosure is to provide a power consumption calculation device, a method, and a computer-readable medium capable of accurately estimating individual power consumption for each of a plurality of devices even in a case where an environment of a place where the plurality of devices are disposed changes.

### Solution to Problem

To achieve the above object, the present disclosure provides a power consumption calculation device as a first aspect. A power consumption calculation device includes an environmental factor acquisition unit that acquires an environmental factor in a place where a plurality of devices are disposed, and an individual power consumption calculation unit that estimates an individual power consumption of each of the plurality of devices based on reference power consumption set for each of the plurality of devices and the acquired environmental factor.

The present disclosure provides a power consumption calculation method as a second aspect. A power consumption calculation method includes acquiring an environmental factor in a place where a plurality of devices are disposed, and estimating an individual power consumption of each of the plurality of devices based on reference power consumption set for each of the plurality of devices and the acquired environmental factor.

The present disclosure provides a computer-readable medium as a third aspect. A computer-readable medium stores a program for causing a processor to execute acquiring an environmental factor in a place where a plurality of devices are disposed, and estimating an individual power consumption of each of the plurality of devices based on reference power consumption set for each of the plurality of devices and the acquired environmental factor.

### Advantageous Effects of Invention

The power consumption calculation device, the method, and the computer-readable medium according to the present disclosure can accurately estimate individual power consumption for each of a plurality of devices even in a case where an environment of a place where the plurality of devices are disposed changes.

### BRIEF DESCRIPTION OF DRAWINGS

FIG. 1 is a block diagram illustrating a schematic configuration example of a power consumption calculation device according to the present disclosure.

FIG. 2 is a block diagram illustrating a system including a power consumption calculation device according to one example embodiment of the present disclosure.

FIG. 3 is a developed perspective view illustrating an example of a multifunction pole on which a plurality of devices are mounted.

FIG. 4 is a block diagram illustrating an example of a configuration of a module.

FIG. 5 is a block diagram illustrating a configuration example of a power consumption calculation device.

FIG. 6 is a block diagram illustrating an example of a configuration of a device that performs analysis processing.

FIG. 7 is a flowchart illustrating an operation procedure of the power consumption calculation device.

FIG. 8 is a block diagram illustrating a hardware configuration example of a computer device.

### EXAMPLE EMBODIMENT

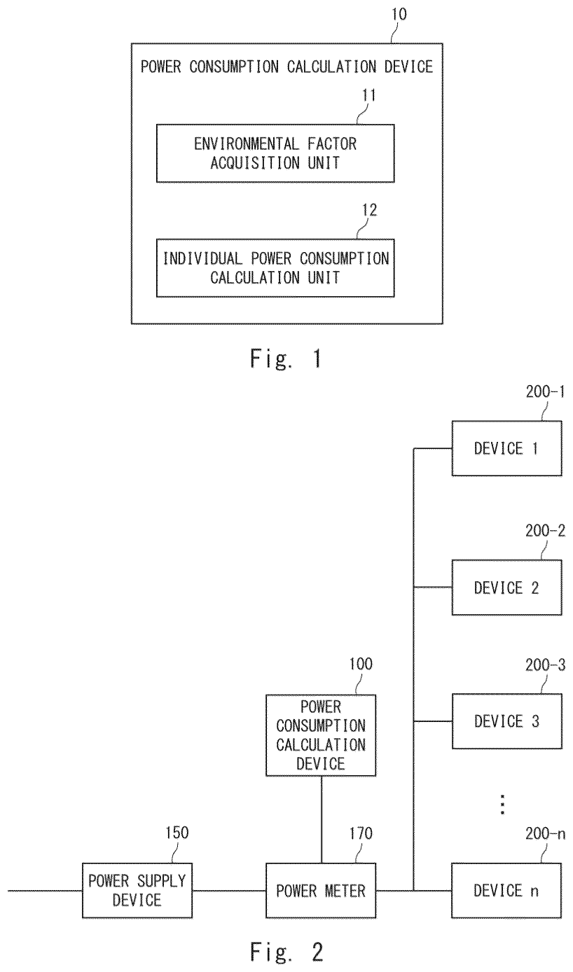

Prior to describing example embodiments of the present disclosure, an overview of the present disclosure will be given. FIG. 1 illustrates a schematic configuration example of a power consumption calculation device according to the present disclosure. A power consumption calculation device 10 includes an environmental factor acquisition unit 11 and an individual power consumption calculation unit 12.

The environmental factor acquisition unit 11 acquires environmental factors in a place where a plurality of devices are placed. Reference power consumption is set for each of the plurality of devices. The individual power consumption calculation unit 12 estimates, for each of the plurality of devices, individual power consumption of each of the plurality of devices based on the reference power consumption set for the device and the environmental factors acquired by the environmental factor acquisition unit 11.

In the present disclosure, the individual power consumption calculation unit 12 estimates the individual power consumption of each device based on the reference power consumption of each device and the environmental factor in the place where the plurality of devices are disposed. The reference power consumption indicates, for example, power consumption of a device in a standard environment. The power consumption calculation device 10 according to the present disclosure calculates an individual power consumption of each device by using environmental factors. Therefore, the power consumption calculation device 10 can accurately estimate the individual power consumption of each of the plurality of devices under various environments.

Hereinafter, example embodiments of the present disclosure will be described in detail with reference to the drawings. In the following description and drawings, omission and simplification are made as appropriate for clarity of description. In each drawing, the same elements and the same elements are denoted by the same reference numerals, and repeated description is omitted as necessary.

FIG. 2 illustrates a system including a power consumption calculation device according to one example embodiment of the present disclosure. The system includes a power consumption calculation device 100, a power supply device 150, a power meter 170, and a plurality of devices 200-1 to 200-n. Note that n is an integer equal to or greater than two.

The power supply device 150 supplies power to the plurality of devices 200-1 to 200-n. The power supply device 150 supplies, for example, commercial AC 100 V power to the plurality of devices 200-1 to 200-n. The power supply device 150 may supply power of a plurality of voltages to the plurality of devices 200-1 to 200-n. The power supply supplied by the power supply device 150 is not limited to the AC power supply, and may include a DC power supply.

The power meter 170 measures the amount of power supplied to the plurality of devices 200-1 to 200-n. In other words, the power meter 170 measures the total amount of power consumed by the plurality of devices 200-1 to 200-n. In the following description, the devices 200-1 to 200-n are also referred to as devices 200 unless they need to be particularly distinguished. The plurality of devices 200 may be devices managed or operated by different companies.

Each of the plurality of devices 200 is a device that operates by receiving power supply from the power supply device 150. The device 200 includes, for example, at least one of an edge computer such as a MEC (Multi-access/Mobile Edge Computing) server, a digital signage, a security camera, a public WiFi (registered trademark), a 5G (5th Generation) base station, a wireless communications device, and an environment sensor. The device 200 may include a PoE (Power over Ethernet) hub. The plurality of devices 200 are mounted on, for example, a multifunction pole on which a plurality of functions is mounted. The plurality of devices 200 may be any devices that receive power supply from the power supply device 150, and are not necessarily mounted on the multifunction pole.

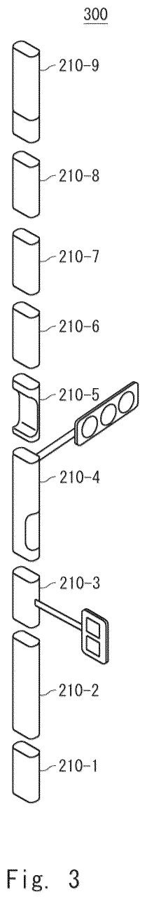

FIG. 3 illustrates an example of a multifunction pole on which a plurality of devices 200 are mounted. In this example, the multifunction pole is configured as a traffic light 300. The traffic light 300 may also be referred to as a smart traffic light or a smart traffic light pole. The traffic light 300 has a plurality of modules 210-1 to 210-9 coupled to each other. The modules 210-1 to 210-9 may also be referred to as a unit or an assembly (ASSY). In the following description, the modules 210-1 to 210-9 are also referred to as modules 210 if it is not particularly necessary to distinguish the modules from each other. For example, the traffic light 300 is disposed at an intersection.

In the present example embodiment, the module 210-1 is, for example, a module constituting a common unit. The device 200 (see FIG. 2) is disposed in at least a part of the modules 210-2 to 210-9. In other words, the plurality of devices 200 are distributed and disposed in the plurality of modules 210 at the traffic light 300.

The module 210-2 is, for example, a module having a function of digital signage. The module 210-2 includes, for example, a control unit such as a display and a controller, and a device such as an edge computer. The module 210-2 may include a speaker and a microphone.

The modules 210-3 and 210-4 are modules having a function of a traffic signal. The module 210-4 is a module having a function of a vehicle traffic signal. The module 210-4 includes a traffic signal lighting device. The traffic signal lighting device has green, yellow, and red lighting devices. An arm of the traffic signal lighting device is attached to the body via an attachment tool. The module 210-4 may include a signal lighting control circuit to control the traffic signal lighting device. A camera used for controlling the traffic signal lighting device may be built in the module 210-4. The module 210-3 is a module having a function of a pedestrian traffic signal. The configuration of the module 210-3 may be similar to the configuration of the module 210-4 except that the traffic signal lighting device is for pedestrians.

The module 210-5 is a module having a function of a security camera. The module 210-5 includes, for example, a camera that photographs the surroundings and devices such as a camera control circuit. The modules 210-6 and 210-7 are modules used to adjust the height or length of the pole. The interior of the modules 210-6 and 210-7 may be hollow. In the modules 210-6 and 210-7, devices having predetermined functions can be mounted in the future.

The module 210-8 is a module having a function of a public WiFi base station. The module 210-8 includes devices such as a wireless antenna and a WiFi transceiver, for example. The module 210-9 is a module having a function of a 5G antenna base station. The module 210-9 includes, for example, devices such as a wireless antenna and a 5G transceiver.

The module 210-1 is a module constituting a common unit, and includes the power supply device 150 and the power meter 170 (see FIG. 2). The power supply device 150 may supply power to the modules 210-2 to 210-9 by a plurality of power supply systems. For example, the power supply device 150 may divide a power supply system into the modules 210-3 and 210-4 having a function of a traffic signal and the modules 210-2, 210-5, 210-8, and 210-9 having other functions, and supply power to each module. In this case, the power meter 170 may measure the total amount of power consumed by the modules 210-2, 210-5, 210-8, and 210-9.

The module 210-1 may have a device such as a network device. The network device is connected to an external network. The device mounted on the modules 210-2 to 210-9 can be configured to be able to communicate with an external network through the network device of the module 210-1. Although the module 210-1 is not particularly limited, for example, at least a part thereof may be embedded in the ground. Alternatively, the module 210-1 may be connected to a foundation disposed on the ground by using a fastening bolt or the like. The module 210-1 may be coupled to a support pillar embedded in the ground. In the present example embodiment, the multifunction pole is not limited to the traffic light 300, and the multifunction pole may be, for example, a pole installed in a park, a shopping center, and a store.

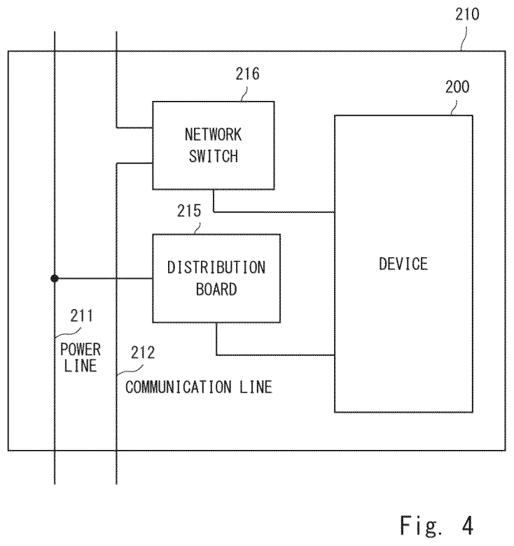

FIG. 4 illustrates an example of a configuration of the module 210. In this example, the module 210 includes a device 200, a power line 211, a communication line 212, a distribution board 215, and a network switch 216. Although not illustrated, the module 210 has an interface for connecting to the module on the lower layer side and an interface for connecting to the module on the upper layer side. In the module 210, the power line 211 and the communication line 212 may be connected to the power line 211 and the communication line 212 disposed in the module on the lower layer side via the interface. The power line 211 and the communication line 212 may be connected to the power line 211 and the communication line 212 disposed in the module on the upper layer side via the interface.

The power line 211 is connected to, for example, the power supply device 150 disposed in the module 210-1 (see FIG. 3) constituting a common unit. In the module 210, the power line 211 is branched into the distribution board 215. The distribution board 215 includes, for example, a circuit breaker having a function such as an earth leakage protection function. The device 200 is connected to the power line 211 via the distribution board 215, and power is supplied from the power line 211 to the device 200.

The communication line 212 is connected to a network device disposed in the module 210-1. In the module 210, the communication line 212 is connected to the network switch 216. The network switch 216 is configured as a network device such as a layer 2 switch, for example. The device 200 is connected to the communication line 212 via the network switch 216. The device 200 can communicate with a device disposed in another module in the traffic light 300 and an external network via the communication line 212.

The device mounted on each module 210 may include a device for stably operating the device in the module in addition to the device for achieving the function provided by each module. For example, each module may include equipment for temperature regulation, such as a heater or cooler. In the following description, “device” may be used as a term meaning a module on which the device is mounted. The “module” can be used as a term meaning equipment mounted on the module.

Here, the company that installs, manages, or operates the traffic light 300 and the company that manages or operates the device in each module 210 may be different. The company that manages or operates the device in each module 210 shall pay the electricity charge to the company that operates the traffic light 300 or the electric power company according to the power consumption amount of the module 210 or the device 200 in the module 210. The electricity charge can be calculated by, for example, a product of a unit price per predetermined amount of power such as 1 kWh and the amount of power individually used by each device 200.

In the present example embodiment, the power consumption calculation device 100 (see FIG. 2) estimates or calculates the individual power consumption of each of the plurality of devices 200. For example, the power consumption calculation device 100 estimates individual power amount consumed by each of the modules 210-2, 210-5, 210-8, and 210-9 in the traffic light 300 illustrated in FIG. 3. The power consumption calculation device 100 calculates the electricity charge of each of the plurality of devices 200 based on the individual power amount.

In the present example embodiment, the power consumption calculation device 100 may be disposed at the same place as the place where the power supply device 150 and the plurality of devices 200 are disposed, or may be disposed at a place different from the power supply device 150 and the plurality of devices 200. For example, the power consumption calculation device 100 is disposed at an intersection where the traffic light 300 is disposed. Alternatively, the power consumption calculation device 100 may be disposed at a place different from the intersection where the traffic light 300 is disposed.

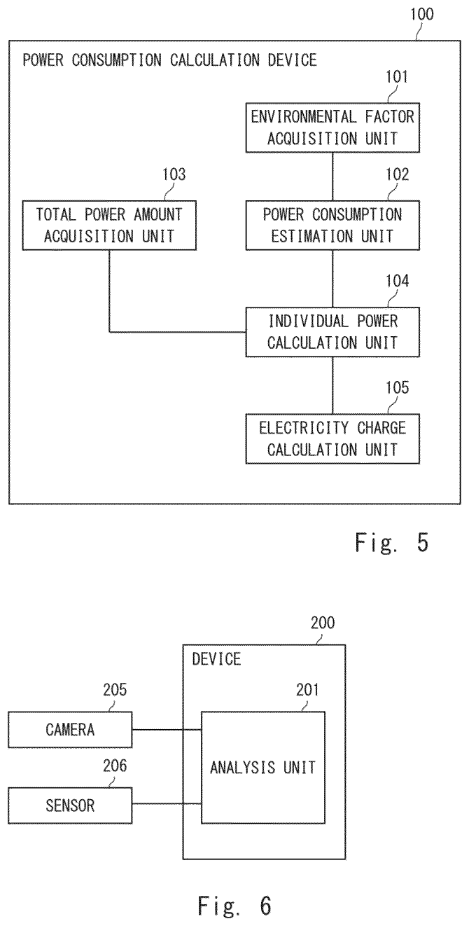

FIG. 5 illustrates a configuration example of the power consumption calculation device 100. The power consumption calculation device 100 includes an environmental factor acquisition unit 101, a power consumption estimation unit 102, a total power amount acquisition unit 103, an individual power calculation unit 104, and an electricity charge calculation unit 105. The power consumption calculation device 100 may be configured as, for example, a device including one or more processors and one or more memories. At least some of the functions of the units in the power consumption calculation device 100 can be implemented by the processor executing processing according to a command read from the memory. The power consumption calculation device 100 is not necessarily configured as a single device. The power consumption calculation device 100 may be configured using a plurality of physically separated devices.

The environmental factor acquisition unit 101 acquires environmental factors in a place where a plurality of devices 200 are placed. The environmental factor includes, for example, a communication environment in a place where the device is disposed, a traffic volume of persons or cars around an intersection, or the like. The environmental factor may include at least one of temperature, brightness, date and time, a time zone, and a season. The plurality of devices 200 are mounted on, for example, the traffic light 300 illustrated in FIG. 3 or are disposed in the vicinity of the traffic light 300 accompanying the traffic light 300. In this case, the environmental factor acquisition unit 101 acquires the environmental factors at the intersection where the traffic light 300 is disposed. The environmental factor acquisition unit 101 is relevant to the environmental factor acquisition unit 11 illustrated in FIG. 1.

The environmental factor acquisition unit 101 may acquire the environmental factor from, for example, a camera and a sensor mounted on any module of the traffic light 300. Alternatively, the environmental factor acquisition unit 101 may acquire a result of the analysis processing performed by any module 210 as an environmental factor.

FIG. 6 illustrates an example of a configuration of the device 200 in a case where the analysis processing is performed in the device 200. The device 200 includes an analysis unit 201. In this example, the device 200 can be configured as a computer device having one or more processors and one or more memories. The function of the analysis unit 201 can be achieved by the processor executing processing according to a command read from the memory.

The analysis unit 201 acquires a camera image or a video from a camera 205. The analysis unit 201 acquires sensor data from a sensor 206. The sensor 206 includes, for example, a sensor such as a temperature sensor, a brightness sensor, or a rain gauge. The camera 205 and the sensor 206 are disposed, for example, in the module 210 in which the device 200 is disposed in the traffic light 300. The camera 205 and the sensor 206 may be disposed in a module different from the module 210 in which the device 200 is disposed in the traffic light 300.

The analysis unit 201 may analyze at least one of the traffic volume of people and the traffic volume of cars at an intersection where the traffic light 300 is disposed using the camera image or the video and the sensor data. The analysis unit 201 may analyze other environmental factors around the intersection in addition to the traffic volume. The analysis unit 201 transmits the analysis result to the power consumption calculation device 100 via the communication line 212. The environmental factor acquisition unit 101 acquires an analysis result in the analysis unit 201 as an environmental factor.

The power consumption estimation unit 102 calculates the estimated power consumption for each of the plurality of devices 200 based on the reference power consumption set for the device 200 and the acquired environmental factor. Here, the reference power consumption indicates power consumption in a predetermined reference environment. The reference power consumption may be, for example, rated power consumption of the device 200. Alternatively, the reference power consumption may be determined based on an actual measurement value of power consumption in a case where the device 200 is operated under a standard environment. For example, the power consumption estimation unit 102 calculates the estimated power consumption suitable for the environment by multiplying the reference power consumption by a coefficient relevant to the environmental factor.

The environmental factor acquisition unit 101 may acquire a plurality of environmental factors. The environmental factors that affect the power consumption of the device 200 may be different for each device 200. The power consumption estimation unit 102 calculates the estimated power consumption for each device 200 using the environmental factor selected according to the characteristic of the device 200 among the plurality of acquired environmental factors. The power consumption estimation unit 102 calculates the estimated power consumption of each device 200 for each predetermined period. The predetermined period may be set to a period such as one day, one week, or one month.

For example, in a case where temperature adjustment or temperature management is performed in the device 200, it is considered that power consumption changes in each device 200 as the temperature adjustment is performed. For example, in a case where the temperature is high, it is conceivable that the power consumption increases due to cooling. Even in a case where the temperature is low, there is a case where a temperature decrease is prevented using a heater or the like, and in this case, it is considered that the power consumption increases. The power consumption estimation unit 102 may use information indicating a season or information on an outdoor temperature as an environmental factor that affects power consumption.

In a case where the device 200 includes a camera, the power consumption of the device 200 can change according to a time zone. Specifically, if the time zone is nighttime, an illuminator such as an infrared light is turned on for photographing, and thus the amount of electricity used may increase as compared with daytime. In a case where the device 200 includes a camera, the power consumption estimation unit 102 may use the information on the time zone as an environmental factor that affects the power consumption. The camera may switch the operation mode from the normal shooting mode to the shooting mode in a dark place if the brightness is lower than a predetermined reference. In that case, the power consumption estimation unit 102 may use information on brightness measured by the sensor as an environmental factor that affects power consumption.

In a case where the device 200 includes a communication terminal device, the power consumption of the device 200 can change according to the communication volume. In a case where the communication terminal device performs wireless communication, the power consumption in the communication terminal device can change according to the wireless communication environment. In a case where the device 200 includes a communication terminal device, the power consumption estimation unit 102 may use the information on the communication volume and the wireless communication environment as an environmental factor that affects the power consumption. In this case, the environmental factor acquisition unit 101 may acquire the information on the communication volume and the wireless communication environment as the environmental factor from the device 200 via the communication line 212 (see FIG. 4), for example.

In a case where the device 200 includes a radio base station, the power consumption of the device 200 may change according to the number of communication terminals connected to the base station. In a case where the device 200 includes a radio base station, the power consumption estimation unit 102 may use information on the number of communication terminals connected to the radio base station as an environmental factor that affects power consumption. In this case, the environmental factor acquisition unit 101 may acquire, as an environmental factor, information on the number of communication terminals connected to the radio base station from the device 200 via the communication line 212, for example.

In a case where the device 200 includes an edge computer, the power consumption of the device 200 can change according to a usage rate of a processor such as a hardware accelerator or a central processing unit (CPU). The usage rate of the hardware accelerator or the CPU is considered to change according to the load of the analysis processing performed by the CPU or the like, and the load of the analysis processing is considered to be related to the traffic volume of people or cars around the intersection. In a case where the device 200 includes an edge computer, the power consumption estimation unit 102 may use information on the traffic volume of persons or cars as an environmental factor that affects power consumption. In this case, the environmental factor acquisition unit 101 may acquire information on the traffic volume of persons or cars as an environmental factor from the device 200 via the communication line 212, for example.

In a case where the device 200 includes a digital signage, the power consumption of the device 200 may vary depending on the number of pedestrians in the surroundings. This is because the digital signage is mainly used to transmit information to pedestrians, and it is considered that the presence or absence of display is switched according to the number of pedestrians. In a case where the device 200 includes digital signage, the power consumption estimation unit 102 may use information on the number of pedestrians as an environmental factor that affects power consumption. In this case, the environmental factor acquisition unit 101 may acquire information on the number of pedestrians as an environmental factor from a digital signage module or another module.

The total power amount acquisition unit 103 acquires the total amount of power consumption of the plurality of devices 200, that is, the total amount of power consumed by the plurality of devices 200 as a whole. The total power amount acquisition unit 103 acquires the total power consumption from the power meter 170 (see FIG. 2), for example.

The individual power calculation unit 104 calculates individual power consumption for each of the plurality of devices 200. In the present example embodiment, the individual power calculation unit 104 calculates the individual power consumption of each of the plurality of devices 200 based on the estimation result of the power consumption of each of the plurality of devices 200 estimated by the power consumption estimation unit 102 and the total power consumption acquired by the total power amount acquisition unit 103. The individual power calculation unit 104 may calculate the individual power consumption of each of the plurality of devices 200 in the predetermined period by integrating the estimation results of the power consumption of each of the plurality of devices 200 estimated by the power consumption estimation unit 102. The power consumption estimation unit 102 and the individual power calculation unit 104 are relevant to the individual power consumption calculation unit 12 illustrated in FIG. 1.

For example, the individual power calculation unit 104 calculates the individual power consumption in the predetermined period by dividing the total power consumption in the predetermined period by the ratio of the estimated power consumption of the plurality of devices 200 in the predetermined period. Specifically, it is assumed that a ratio of the estimated power consumption of a device A, the estimated power consumption of a device B, and the estimated power consumption of a device C is 3:3:1. In that case, the individual power calculation unit 104 calculates the individual power consumption of each device by dividing the total power consumption by the ratio of 3:3:1. In this case, the individual power consumption of the device A is total power consumption×3/7, the individual power consumption of the device B is total power consumption×3/7, and the individual power consumption of the device C is total power consumption×1/7.

The electricity charge calculation unit 105 calculates an electricity charge based on the individual power consumption of each device 200 calculated by the individual power calculation unit 104. For example, the electricity charge calculation unit 105 calculates an electricity charge for each of the plurality of devices 200 based on an amount of power individually used and a unit price per predetermined power amount. The electricity charge calculation unit 105 may calculate the entire electricity charge based on the total power consumption and the unit price per predetermined power amount, and divide the calculated entire electricity charge by the ratio of the amount of power individually used to calculate the electricity charge of each device 200.

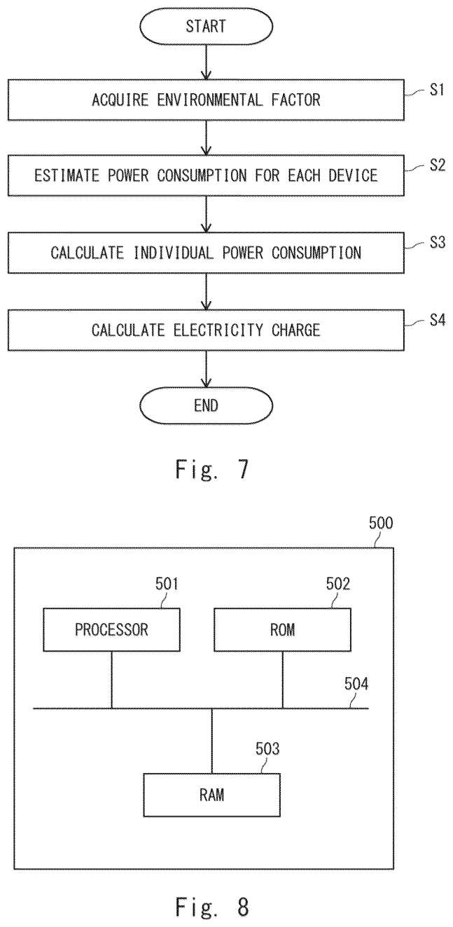

Next, an operation procedure will be described. FIG. 7 illustrates an operation procedure of the power consumption calculation device 100. The operation procedure of the power consumption calculation device 100 is relevant to a power consumption calculation method or an electricity charge calculation method. The environmental factor acquisition unit 101 acquires environmental factors in a place where a plurality of devices 200 are placed (step S1). In step S1, for example, the environmental factor acquisition unit 101 acquires the environmental factor at the intersection where the traffic light 300 illustrated in FIG. 3 is disposed.

The power consumption estimation unit 102 estimates the power consumption of each device 200 based on the environmental factor acquired in step S1 and the reference power consumption of each device 200 (step S2). In other words, the power consumption estimation unit 102 calculates the estimated power consumption based on the environmental factor and the reference power consumption for each device 200. In step S2, the power consumption estimation unit 102 calculates the estimated power consumption of the device 200 mounted on the module 210 or the module 210 itself.

The total power amount acquisition unit 103 acquires the total power consumption of the plurality of devices 200 in the predetermined period from the power meter 170 (see FIG. 2). The individual power calculation unit 104 calculates an individual power consumption for each device 200 based on the estimated power consumption calculated in step S2 and the total power consumption (step S3). In step S3, for example, the individual power calculation unit 104 calculates the individual power consumption of each device by dividing the total power consumption by the ratio of the estimated power consumption of each device 200. The electricity charge calculation unit 105 calculates the electricity charge of each device 200 based on the individual power consumption (step S4).

For example, the traffic light 300 illustrated in FIG. 3 has a plurality of modules 210 providing functions such as an edge computer, a digital signage, a security camera, public WiFi, and a 5G base station. In a smart traffic light pole such as the traffic light 300, it is assumed that a plurality of companies each mount the module 210 in one traffic light pole, and each company provides each service.

At the traffic light 300, each module 210 needs to be powered. If the power line can be individually disposed in each module 210 in the traffic light 300, it is considered that the power consumption of each module can be accurately measured. However, in a limited space of the traffic light 300, it is difficult to individually dispose power lines in each module 210. It is difficult to individually dispose the electric energy meters in each module 210 due to space restrictions and the like.

For example, a company that operates the traffic light 300 pays an electricity charge relevant to the total power consumption of the plurality of devices 200 or the plurality of modules 210 to an electric power company. The company operating the traffic light 300 charges the company of each module an electricity charge relevant to the individual power consumption of each module 210. In this case, the company operating the traffic light 300 can grasp the total power consumption of the plurality of modules 210 as a whole, but for the above reason, it is difficult to directly measure the individual power consumption of each module 210.

In the present example embodiment, the environmental factor acquisition unit 101 acquires an environmental factor of a place where the plurality of modules 210 are disposed. The power consumption estimation unit 102 estimates the power consumption of each module 210 based on the acquired environmental factor and the reference power consumption of each module 210. The individual power calculation unit 104 calculates an individual power consumption for each module 210 based on the estimated power consumption of each module 210 and the total power consumption. In the present example embodiment, the power consumption of each module 210 is estimated using environmental factors. Therefore, even if the power consumption of each module 210 fluctuates according to environmental factors, the individual power calculation unit 104 can accurately estimate the individual power consumption consumed in each module 210 to some extent.

In the present example embodiment, the electricity charge calculation unit 105 calculates the electricity charge of each module 210 based on the individual power consumption of each module 210. The company operating the traffic light 300 can charge the company of each module 210 the electricity charge calculated for each module 210. As described above, in the present example embodiment, the individual power consumption consumed in each module 210 can be accurately estimated to some extent. Therefore, the company of each device 200 or each module 210 can pay the electricity charge relevant to the amount of power consumed in each module 210.

In the above example embodiment, an example has been described in which the power consumption calculation device 100 calculates, for example, the individual power consumption of the plurality of modules 210 mounted on one traffic light 300 and the electricity charge. However, the present disclosure is not limited to the above-described example embodiments. For example, one power consumption calculation device 100 may be disposed for a plurality of traffic lights 300. In this case, for example, the power consumption calculation device 100 may calculate the individual power consumption and the electricity charge of the plurality of modules 210 for each of the plurality of traffic lights 300 in the same intersection.

For example, there may be a case where the power consumption and the amount of power individually used can be accurately acquired for some devices 200 among the plurality of devices 200. In that case, the power consumption estimation unit 102 may calculate the estimated power consumption based on the environmental factor and the reference power consumption for the device 200 from which the individual power consumption cannot be accurately acquired. The individual power calculation unit 104 may estimate the amount of power individually used for the device 200 from which the individual power consumption cannot be accurately acquired. The electricity charge calculation unit 105 may calculate the electricity charge for the device 200 that cannot accurately acquire the individual power consumption. For the device 200 that can accurately acquire the individual power consumption, the electricity charge can be calculated using the accurately acquired individual power consumption.

In the above example embodiment, the example has been described in which the total power consumption of the plurality of modules is acquired and the individual power consumption and the electricity charge are calculated in units of modules 210. However, the present disclosure is not limited to the above-described example embodiments. For example, in a case where the power consumption amount is measured or acquired in units of modules, the power consumption estimation unit 102 may calculate the estimated power consumption for each of the plurality of devices in the module 210 based on the environmental factor and the reference power consumption of each of the plurality of devices in the module 210. In this case, the power consumption amount measured in units of malls can be decomposed into the power consumption amounts of the plurality of devices in the module.

Next, a hardware configuration of the power consumption calculation device 100 will be described. FIG. 8 illustrates an example of a hardware configuration of a computer device that can be used for the power consumption calculation device 100. A computer device 500 includes a processor 501 such as a CPU, a read only memory (ROM) 502, and a random access memory (RAM) 503. In the computer device 500, the processor 501, the ROM 502, and the RAM 503 are connected to one another via a bus 504. Although not illustrated, the computer device 400 may include other circuits such as a peripheral circuit, a communication circuit, and an interface circuit.

The ROM 502 is a nonvolatile storage device. For example, a semiconductor storage device such as a flash memory having a relatively small capacity is used for the ROM 502. The ROM 502 stores a program executed by the processor 501.

The program described above includes commands (or software codes) for causing a computer to perform one or more functions described in the example embodiments in a case where the program is read by the computer. The program may be stored in a non-transitory computer-readable medium or in a tangible storage medium. As an example and not by way of limitation, the computer-readable medium or the tangible storage medium includes a RAM, a ROM, a flash memory, an SSD or any other memory technology, a compact disc (CD), a digital versatile disc (DVD), a Blu-ray (registered trademark) disk or any other optical disk storage, a magnetic cassette, a magnetic tape, a magnetic disk storage or any other magnetic storage device. The program may be transmitted on a transitory computer-readable medium or a communications medium. As an example and not by way of limitation, the transitory computer-readable medium or the communication medium includes electrical, optical, acoustic, or other forms of propagated signals.

The RAM 503 is a volatile storage device. As the RAM 503, various types of semiconductor memory devices such as a dynamic random access memory (DRAM) or a static random access memory (SRAM) are used. The RAM 503 can be used as an internal buffer for transitorily storing data and the like.

The processor 501 develops the program stored in the ROM 502 on the RAM 503, and executes the program. Functions of the units in the power consumption calculation device 100 can be achieved by the CPU 501 executing the program.

Although example embodiments according to the present disclosure have been described above in detail, the present disclosure is not limited to the above-described example embodiments, and the present disclosure also includes those that are obtained by making changes or modifications to the above-described example embodiments without departing from the spirit of the present disclosure.

The whole or part of the example embodiments disclosed above can be described as, but not limited to, the following Supplementary notes.

### Supplementary Note 1

A power consumption calculation device including:
an environmental factor acquisition unit that acquires an environmental factor in a place where a plurality of devices are disposed; and
an individual power consumption calculation unit that estimates an individual power consumption of each of the plurality of devices based on reference power consumption set for each of the plurality of devices and the acquired environmental factor.

### Supplementary Note 2

The power consumption calculation device according to Supplementary Note 1, in which the plurality of devices are mounted on a multifunction pole configured to be mountable with one or more devices, or is disposed accompanying the multifunction pole.

### Supplementary Note 3

The power consumption calculation device according to Supplementary Note 1 or 2, in which the environmental factor acquisition unit acquires, as the environmental factor, at least one of a communication volume of communication performed by the device and a traffic volume of a place where the plurality of devices are disposed.

### Supplementary Note 4

The power consumption calculation device according to Supplementary Note 3, in which
at least one of the plurality of devices includes an analysis unit that analyzes a traffic volume of a place where the plurality of devices are disposed, and
the environmental factor acquisition unit acquires a traffic volume analyzed by the analysis unit as an environmental factor.

### Supplementary Note 5

The power consumption calculation device according to any one of Supplementary Notes 1 to 4, in which the environmental factor acquisition unit acquires at least one of temperature, brightness, date and time, a time zone, and a season as the environmental factor.

### Supplementary Note 6

The power consumption calculation device according to any one of Supplementary Notes 1 to 5, in which
the environmental factor acquisition unit acquires a plurality of environmental factors, and
the individual power consumption calculation unit estimates the individual power consumption for each of the plurality of devices using one or more environmental factors selected according to the device among the plurality of environmental factors.

### Supplementary Note 7

The power consumption calculation device according to any one of Supplementary Notes 1 to 6, in which the individual power consumption calculation unit calculates estimated power consumption based on the reference power consumption and the environmental factor for each of a plurality of devices, and estimates the individual power consumption in a predetermined period based on the calculated estimated power consumption.

### Supplementary Note 8

The power consumption calculation device according to Supplementary Note 7, further including a total power amount acquisition unit that acquires a total power consumption consumed by the plurality of devices in the predetermined period,
in which the individual power consumption calculation unit estimates the individual power consumption by dividing the total power consumption by a ratio of estimated power consumption of the plurality of devices.

### Supplementary Note 9

The power consumption calculation device according to any one of Supplementary Notes 1 to 8, further including an electricity charge calculation unit that calculates an electricity charge of each of the plurality of devices based on the individual power consumption.

### Supplementary Note 10

A power consumption calculation method including:
acquiring an environmental factor in a place where a plurality of devices are disposed; and
estimating an individual power consumption of each of the plurality of devices based on reference power consumption set for each of the plurality of devices and the acquired environmental factor.

### Supplementary Note 11

The power consumption calculation method according to Supplementary Note 10, further including calculating an electricity charge of each of the plurality of devices based on the individual power consumption.

### Supplementary Note 12

A non-transitory computer-readable medium storing a program for causing a processor to execute:
acquiring an environmental factor in a place where a plurality of devices are disposed; and
estimating an individual power consumption of each of the plurality of devices based on reference power consumption set for each of the plurality of devices and the acquired environmental factor.

### Reference Signs List

10 power consumption calculation device
11 environmental factor acquisition unit
12 individual power calculation unit
100 power consumption calculation device
101 environmental factor acquisition unit
102 power consumption estimation unit
103 total power amount acquisition unit
104 individual power calculation unit
105 electricity charge calculation unit
150 power supply device
170 power meter
200 device
201 analysis unit
205 camera
206 sensor
210 module
211 power line
212 communication line
215 distribution board
216 network switch
500 computer device
501 processor
502 ROM
503 RAM
504 bus

What is claimed is:

1. A power consumption calculation device comprising:
at least one memory storing instructions; and
at least one processor configured to execute the instructions to:
acquire an environmental factor in a place where a plurality of devices are disposed; and
estimate an individual power consumption of each of the plurality of devices based on reference power consumption set for each of the plurality of devices and the acquired environmental factor.

2. The power consumption calculation device according to claim 1, wherein the plurality of devices are mounted on a multifunction pole configured to be mountable with one or more devices, or is disposed accompanying the multifunction pole.

3. The power consumption calculation device according to claim 1, wherein the at least one processor is configured to execute the instructions to acquire, as the environmental factor, at least one of a communication volume of communication performed by the device and a traffic volume of a place where the plurality of devices are disposed.

4. The power consumption calculation device according to claim 3, wherein
the traffic volume of a place where the plurality of devices are disposed is analyzed by at least one of the plurality of devices, and
the at least one processor is configured to execute the instructions to acquire the analyzed traffic volume as an environmental factor.

5. The power consumption calculation device according to claim 1, wherein the at least one processor is configured to execute the instructions to acquire at least one of temperature, brightness, date and time, a time zone, and a season as the environmental factor.

6. The power consumption calculation device according to claim 1, wherein the at least one processor is configured to execute the instructions to:
acquire a plurality of environmental factors, and
estimate the individual power consumption for each of the plurality of devices using one or more environmental factors selected according to the device among the plurality of environmental factors.

7. The power consumption calculation device according to claim 1, wherein the at least one processor is configured to execute the instructions to calculate estimated power consumption based on the reference power consumption and the environmental factor for each of a plurality of devices, and estimate individual power consumption in a predetermined period based on the calculated estimated power consumption.

8. The power consumption calculation device according to claim 7, wherein the at least one processor is configured to execute the instructions to:
acquire total power consumption consumed by the plurality of devices in the predetermined period, and
estimate the individual power consumption by dividing the total power consumption by a ratio of estimated power consumption of the plurality of devices.

9. The power consumption calculation device according to claim 1, wherein the at least one processor is configured to execute the instructions to calculate an electricity charge of each of the plurality of devices based on the individual power consumption.

10. A power consumption calculation method comprising:
acquiring an environmental factor in a place where a plurality of devices are disposed; and
estimating an individual power consumption of each of the plurality of devices based on reference power consumption set for each of the plurality of devices and the acquired environmental factor.

11. The power consumption calculation method according to claim 10, further comprising calculating an electricity charge of each of the plurality of devices based on the individual power consumption.

12. A non-transitory computer-readable medium storing a program for causing a processor to execute:
acquiring an environmental factor in a place where a plurality of devices are disposed; and
estimating an individual power consumption of each of the plurality of devices based on reference power consumption set for each of the plurality of devices and the acquired environmental factor.
